(19) United States
(12) Patent Application Publication
(10) Pub. No.: US 2024/0213799 A1
(43) Pub. Date: Jun. 27, 2024

(54) ELECTRICAL OUTLET POWER BANK SYSTEM

(71) Applicant: Bryan Gilmore, Prosper, TX (US)

(72) Inventor: Bryan Gilmore, Prosper, TX (US)

(21) Appl. No.: 18/086,222

(22) Filed: Dec. 21, 2022

(51) Int. Cl. H02J 9/06; G01R 22/06; H01M 10/46; H02J 7/00

(52) U.S. Cl. CPC H02J 9/068; G01R 22/065; H01M 10/46; H02J 7/0063; H02J 7/0068

(57) ABSTRACT

An electrical outlet power bank system for receiving electricity from a power bank includes a power grid being a source of electricity. An electric meter is electrically coupled to the power grid. A circuit breaker is electrically coupled to the electric meter and is actuated to open or close a flow of electricity from the power grid. An electrical outlet is electrically coupled to the circuit breaker and receives an electrical plug. A power bank is electrically coupled to the electrical outlet and to the circuit breaker and receives and stores electricity from the power grid, wherein the power bank is actuated to provide electricity to the electrical outlet when the circuit breaker closes the flow of electricity from the power grid.

### CROSS-REFERENCE TO RELATED APPLICATIONS

Not Applicable

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC OR AS A TEXT FILE VIA THE OFFICE ELECTRONIC FILING SYSTEM

Not Applicable

### STATEMENT REGARDING PRIOR DISCLOSURES BY THE INVENTOR OR JOINT INVENTOR

Not Applicable

### BACKGROUND OF THE INVENTION

### (1) Field of the Invention

The disclosure relates to electrical outlets and more particularly pertains to a new electrical outlet for receiving electricity from a power bank.

### (2) Description of Related Art Including Information Disclosed Under 37 CFR 1.97 and 1.98

The prior art relates to electrical outlets and includes a variety of electrical outlets receiving electricity from a power grid. Known prior art does not include an electrical outlet receiving electricity from a power bank that is mounted to the outlet when the electrical outlet loses connection to the power grid.

### BRIEF SUMMARY OF THE INVENTION

An embodiment of the disclosure meets the needs presented above by generally comprising a power grid being a source of electricity. An electric meter is electrically couplable to the power grid. A circuit breaker is electrically couplable to the electric meter and is actuated to open or close a flow of electricity from the power grid. An electrical outlet is electrically couplable to the circuit breaker and is receivable for an electrical plug. A power bank is mounted to the electrical outlet and is electrically coupled to the electrical outlet and to the circuit breaker. The power bank receives and stores electricity from the power grid, wherein the power bank is actuated to provide electricity to the electrical outlet when the circuit breaker closes the flow of electricity from the power grid.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF SEVERAL VIEWS OF THE DRAWING(S)

The disclosure will be better understood and objects other than those set forth above will become apparent when consideration is given to the following detailed description thereof. Such description makes reference to the annexed drawings wherein:

FIG. 1 is a top isometric view of an electrical outlet power bank system according to an embodiment of the disclosure.

FIG. 2 is a side in-use view of an embodiment of the disclosure.

FIG. 3 is a block diagram view of an embodiment of the disclosure.

FIG. 4 is an in-use view of an embodiment of the disclosure.

### DETAILED DESCRIPTION OF THE INVENTION

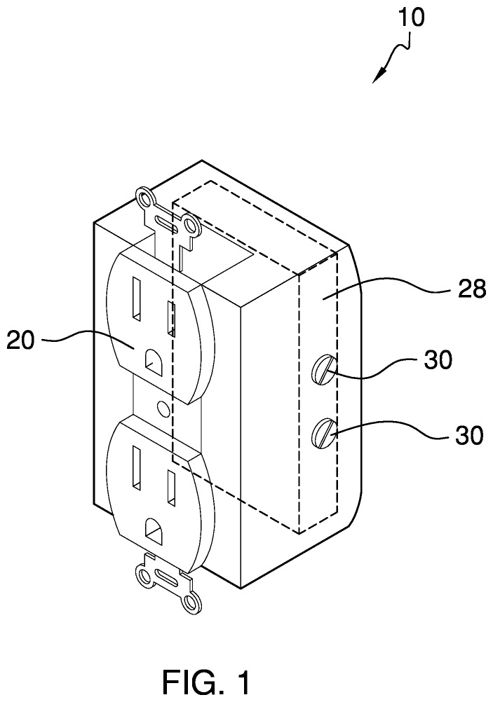

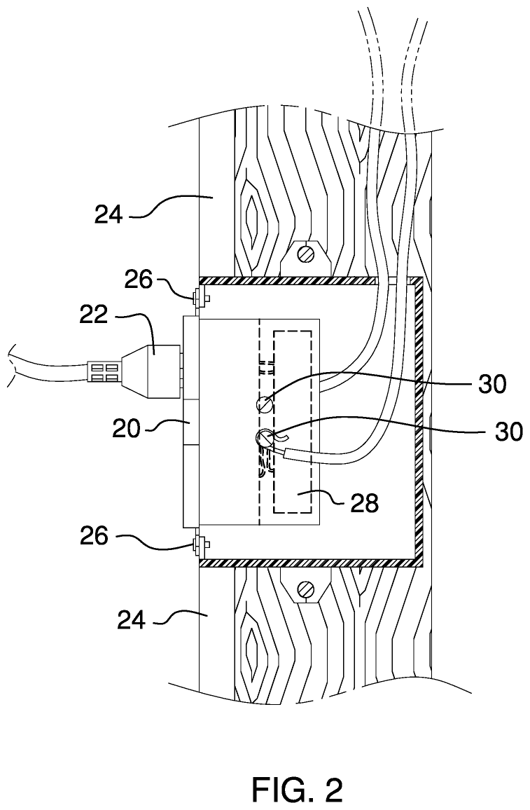

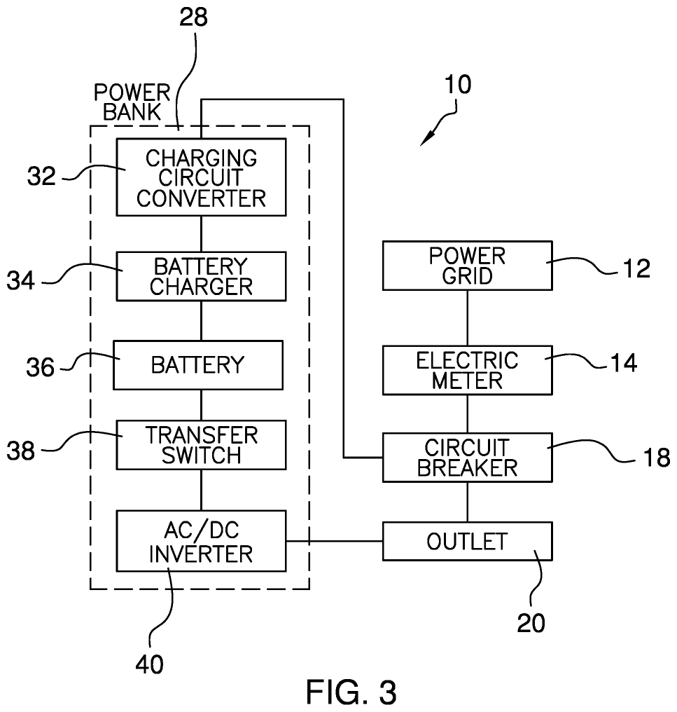

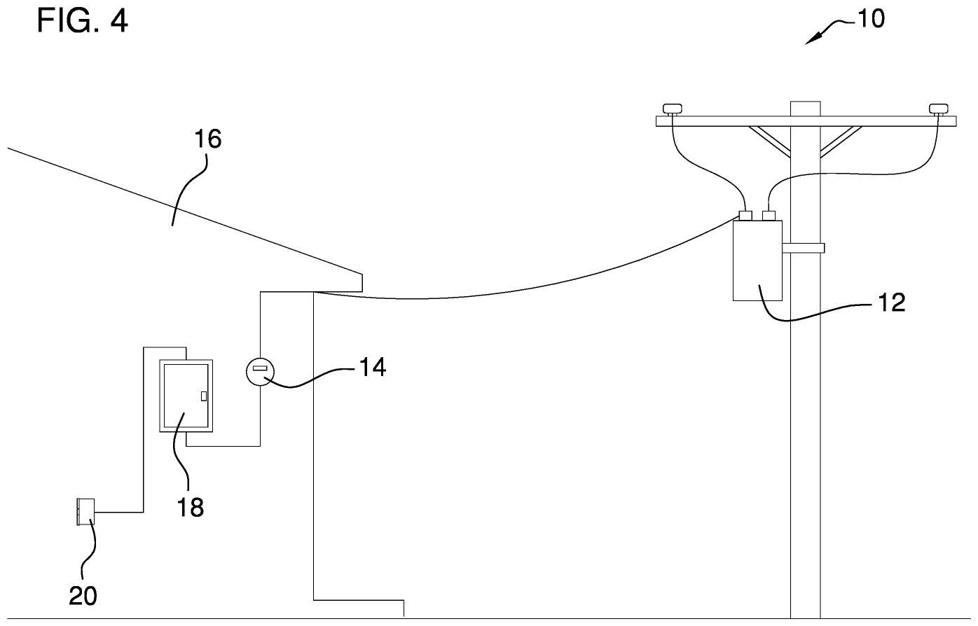

With reference now to the drawings, and in particular to FIGS. 1 through 4 thereof, a new electrical outlet embodying the principles and concepts of an embodiment of the disclosure and generally designated by the reference numeral 10 will be described.

As best illustrated in FIGS. 1 through 4, the electrical outlet power bank system 10 generally comprises a power grid 12 being a source of electricity. The power grid 12 may comprise an overhead power line or another conventional power source. An electric meter 14 is electrically couplable to the power grid 12 and monitors the amount of electricity received from the power grid 12. The electric meter 14 is typically mounted to a dwelling 16 or another building receiving electricity from the power grid 12. A circuit breaker 18 is electrically couplable to the electric meter 14 and is actuated to open or close a flow of electricity from the power grid 12. The circuit breaker 18 may close the flow of electricity when the power grid 12 is unable to provide electricity such as when the overhead power line is damaged during a storm. The circuit breaker 18 typically comprises a fuse box.

An electrical outlet 20 is electrically couplable to the circuit breaker 18 and is receivable for an electrical plug 22. The electrical outlet 20 is typically mounted to a wall 24 by a coupler 26 such as a screw. A power bank 28 is electrically coupled to the electrical outlet 20 and to the circuit breaker 18 and is capable of receiving and storing electricity from the power grid 12, wherein the power bank 28 is actuated to provide electricity to the electrical outlet 20 when the circuit breaker 18 closes the flow of electricity from the power grid 12. The power bank 28 is mountable to the electrical outlet 20 and is normally positioned within the wall 24. A fastener 30 may be used to mount the power bank 28 to the electrical outlet 20. The fastener 30 may comprise a bolt or another conventional fastener.

The power bank 28 includes a converter 32 being electrically couplable to the circuit breaker 18 and being capable of receiving electricity from the power grid 12 to generate a voltage level storable within the power bank 28. A charger 34 is electrically coupled to the converter 32 and receives electricity from the converter 32 after the voltage level has been lowered by the converter 32. A battery 36 is electrically coupled to the charger 34 and stores the electricity from the charger 34. The battery 36 is capable of storing enough electricity to provide power to the electrical outlet 20 for 1 hour to 5 hours, depending on an amount of power being used by the electrical plug 22 connected to the electrical outlet 20.

A transfer switch 38 is electrically coupled to the battery 36 and to the circuit breaker 18 and is actuated to allow electrical connection from said battery 36 to the electrical outlet 20 when said circuit breaker 18 stops the flow of electricity from the power grid 12 to the electrical outlet 20. An inverter 40 may be electrically coupled to the transfer switch 38 and may be electrically couplable to the electrical outlet 20. The invert 36 is capable of inverting electricity from direct current to alternating current, wherein the electrical outlet 20 is capable of providing alternating electrical current to the electrical plug 22.

In use, the power grid 12 provides electricity to the electrical outlet 20 and to the power bank 28, wherein the power bank 28 stores the electricity received. When the flow of electricity from the power grid 12 to the electrical outlet 20 is closed, the transfer switch 38 is actuated by the circuit breaker 18 to provide electricity from the battery 36 of the power bank 28 to the electrical outlet 20.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be only one of the elements.

I claim:

1. A secondary power system comprising:
a power grid being a source of electricity;
an electric meter being electrically couplable to said power grid;
a circuit breaker being electrically couplable to said electric meter and being actuated to open or close a flow of electricity from said power grid;
an electrical outlet being electrically couplable to said circuit breaker and being receivable for an electrical plug;
a power bank being mounted to said electrical outlet and being electrically coupled to said electrical outlet and to said circuit breaker, said power bank receiving and storing electricity from said power grid, wherein said power bank is actuated to provide electricity to said electrical outlet when said circuit breaker closes the flow of electricity from said power grid.

2. The secondary power system of claim 1, wherein said power bank is mountable to said electrical outlet.

3. The secondary power system of claim 1, wherein said power bank includes a converter being electrically couplable to said circuit breaker and being capable of receiving electricity from said power grid to generate a voltage level storable within said power bank.

4. The secondary power system of claim 3, further including a charger being electrically coupled to said converter and receiving electricity from said converter.

5. The secondary power system of claim 4, further including a battery being electrically coupled to said charger and storing said electricity from said charger.

6. The secondary power system of claim 5, further including a transfer switch being electrically coupled to said battery and to said circuit breaker and being actuated to allow electrical connection from said battery to said electrical outlet.

7. The secondary power system of claim 6, further including an inverter being electrically coupled to said transfer switch and being electrically couplable to said electrical outlet, said invert being capable of inverting electricity from direct current to alternating current.

8. A secondary power system comprising:
a power grid being a source of electricity;
an electric meter being electrically couplable to said power grid;
a circuit breaker being electrically couplable to said electric meter and being actuated to open or close a flow of electricity from said power grid;
an electrical outlet being electrically couplable to said circuit breaker and being receivable for an electrical plug;
a power bank being mounted to said electrical outlet and being electrically coupled to said electrical outlet and to said circuit breaker, said power bank receiving and storing electricity from said power grid, wherein said power bank is actuated to provide electricity to said electrical outlet when said circuit breaker closes the flow of electricity from said power grid, said power bank being mountable to said electrical outlet, said power bank including:
a converter being electrically couplable to said circuit breaker and being capable of receiving electricity from said power grid to generate a voltage level storable within said power bank;
a charger being electrically coupled to said converter and receiving electricity from said converter;
a battery being electrically coupled to said charger and storing said electricity from said charger;
a transfer switch being electrically coupled to said battery and to said circuit breaker and being actuated to allow electrical connection from said battery to said electrical outlet; and
an inverter being electrically coupled to said transfer switch and being electrically couplable to said electrical outlet, said invert being capable of inverting electricity from direct current to alternating current.
